(19) United States
(12) Patent Application Publication
(10) Pub. No.: US 2017/0018642 A1
(43) Pub. Date: Jan. 19, 2017

(54) SEMICONDUCTOR DEVICE

(71) Applicant: DENSO CORPORATION, Kariya-city, Aichi-pref. (JP)

(72) Inventors: Yuma KAGATA, Kariya-city (JP); Nozomu AKAGI, Kariya-city (JP)

(21) Appl. No.: 15/123,755

(22) PCT Filed: Mar. 16, 2015
(86) PCT No.: PCT/JP2015/001440

§ 371 Date: Sep. 6, 2016

(30) Foreign Application Priority Data
Mar. 20, 2014 (JP) 2014-058060
Dec. 18, 2014 (JP) 2014-256396

(51) Int. Cl. H01L 29/78; H01L 29/06; H01L 29/15

(52) U.S. Cl. CPC H01L 29/7811; H01L 29/157; H01L 29/7813; H01L 29/0623

(57) ABSTRACT

A semiconductor device includes a first conductivity type region provided to at least one of a second conductivity type column region and a second conductivity type layer located on the second conductivity type column region. The first conductivity type region has a non-depletion layer region when a voltage between a first electrode and a second electrode is 0V. When the voltage between the first electrode and the second electrode is a predetermined voltage, a depletion layer formed on interfaces between a first conductivity type column region and the second conductivity type column region as well as the first conductivity type column region and the second conductivity type layer and a depletion layer formed between the first conductivity type region and an interface of a region provided with the first conductivity type region connect to each other.

### CROSS REFERENCE TO RELATED APPLICATIONS

This application is a U.S. national stage application of International Patent Application No. PCT/JP2015/001440 filed on Mar. 16, 2015 and is based on Japanese Patent Application No. 2014-58060 filed on Mar. 20, 2014 and Japanese Patent Application No. 2014-256396 filed on Dec. 18, 2014, the disclosures of which are incorporated herein by reference.

### TECHNICAL FIELD

The present disclosure relates to a semiconductor device having a super-junction structure (hereinafter, referred to as SJ structure) in which N-type column regions as drift regions and P-type column regions are disposed.

### BACKGROUND

A semiconductor device having an SJ structure in which N-type column regions as drift regions and P-type column regions are disposed so as to alternate repetitively has been proposed (for example, see Patent Literature 1). More specifically, in the proposed semiconductor device, a base layer is provided on the SJ structure and a source layer is provided at a surface-layer portion of the base layer. A trench penetrating through the source layer and the base layer to the N-type column region is provided and a gate insulating film and a gate electrode are sequentially provided in the trench.

A source electrode to be electrically connected to the source layer and the base layer is provided on the base layer and a drain electrode to be electrically connected to a drain layer is provided on the drain layer.

The P-type column regions and the N-type column regions have equal column widths and equal impurity concentration to maintain a charge balance.

Patent Literature 1: JP 2009-200300 A

### SUMMARY

In the semiconductor device described above, however, the potential of the P-type column region is equal to a source potential (potential of the base layer) and therefore a drain-source capacitance becomes larger. Accordingly, an output capacitance loss which results in a switching loss may possibly be increased.

Also, in the semiconductor device described above, hard recovery occurs when a diode operation changes from an ON state to an OFF state, because carriers accumulated in the P-type column region and the N-type column region are abruptly extracted from the source electrode through the P-type column region. Hence, recovery noises and a surge voltage may possibly be increased.

In view of the foregoing issues, the present disclosure has an object to restrict an increase in recovery noises and a surge voltage while reducing an output capacitance loss in a semiconductor device having an SJ structure.

A semiconductor device according to a first aspect of the present disclosure includes a semiconductor substrate having a first conductivity type or second conductivity type semiconductor layer, a first conductivity type column region provided on the semiconductor layer, a second conductivity type column region provided on the semiconductor layer and forming an SJ structure together with the first conductivity type column region, and a second conductivity type layer provided on the first conductivity type column region and the second conductivity type column region. The semiconductor device allows a current to flow between a first electrode electrically connected to the semiconductor layer and a second electrode electrically connected to the second conductivity type layer.

The semiconductor device further includes a first conductivity type region provided to at least one of the second conductivity type column region and a second conductivity type layer located on the second conductivity type column region. The first conductivity type region has a non-depletion layer region when a voltage between the first electrode and the second electrode is 0 V. When the voltage between the first electrode and the second electrode is a predetermined voltage, a depletion layer formed on interfaces between the first conductivity type column region and the second conductivity type column region as well as the first conductivity type column region and the second conductivity type layer and a depletion layer formed between the first conductivity type region and an interface of a region provided with the first conductivity type region connect to each other.

Owing to the configuration as above, the second conductivity type column region can be in a floating state, because the depletion layer formed on the interfaces between the first conductivity type column region and the second conductivity type column region as well as the first conductivity type column region and the second conductivity type layer and the depletion layer formed between the first conductivity type region and an interface of a region provided with the first conductivity type region connect to each other. Consequently, a drain-source capacitance can be smaller and hence an output capacitance loss can be reduced.

The first conductivity type region is provided to at least one of the second conductivity type column region and the second conductivity type layer located on the second conductivity type column region. Hence, the first conductivity type region serves as a barrier when a diode operation changes from an ON state to an OFF state and carriers within the first conductivity type column region and the second conductivity type column region are extracted from the second electrode through the second conductivity type column region. Hence, the semiconductor device has soft recovery by which carriers are extracted moderately into the second electrode. Consequently, an increase in recovery noises and a surge voltage can be restricted.

According to a second aspect of the present disclosure, the semiconductor device of the first aspect may be configured in such a manner that when the voltage between the first electrode and the second electrode is 0 V, the depletion layer formed on the interfaces between the first conductivity type column region and the second conductivity type column region as well as the first conductivity type column region and the second conductivity type layer and the depletion layer formed between the first conductivity type region and the interface of the region provided with the first conductivity type region connect to each other.

Owing to the configuration as above, a drain-source capacitance when the voltage between the first electrode and the second electrode is 0, that is, in an OFF state in which the current does not flow between the first electrode and the second electrode, can be smaller (see FIG. 5). Consequently, a variation in drain-source capacitance when the semiconductor device is completely depleted can be lessened and hence occurrences of switching noises and a gate malfunction can be restricted.

According to a third aspect of the present disclosure, the semiconductor device of the first or second aspect may be configured in such a manner that a charge amount per unit area of the first conductivity type region is 2.0×10⁻⁸ C/cm² or higher (see FIG. 9). Owing to the configuration as above, an output capacitance loss can be reduced.

According to a fourth aspect of the present disclosure, the semiconductor device of any one of the first through third aspects may be configured in such a manner that a charge amount per unit area of the first conductivity type region is 3.0×10⁻⁷ C/cm² or lower (see FIG. 8). Owing to the configuration as above, a decrease in a breakdown voltage can be restricted.

### BRIEF DESCRIPTION OF DRAWINGS

The above and other objects, features and advantages of the present disclosure will become more apparent from the following detailed description made with reference to the accompanying drawings, in which:

FIG. 1 is a sectional view of a semiconductor device according to a first embodiment of the present disclosure;

FIG. 2 is a view showing surplus concentration in a depth direction of a semiconductor substrate;

FIG. 3A is a view showing a state of depletion layers in the semiconductor device shown in FIG. 1;

FIG. 3B is a view showing another state of the depletion layers in the semiconductor device shown in FIG. 1;

FIG. 3C is a view showing still another state of the depletion layers in the semiconductor device shown in FIG. 1;

FIG. 3D is a view showing still another state of the depletion layers in the semiconductor device shown in FIG. 1;

FIG. 4A is a view showing a state of depletion layers in a semiconductor device of a comparative example;

FIG. 4B is a view showing another state of the depletion layers in the semiconductor device of the comparative example;

FIG. 4C is a view showing still another state of the depletion layers in the semiconductor device of the comparative example;

FIG. 5 shows a simulation result indicating a relation between a drain-source voltage and a drain-source capacitance;

FIG. 6 shows a simulation result indicating a relation between a thickness of an N-type region and a breakdown voltage;

FIG. 7 shows a simulation result indicating a relation between impurity concentration of the N-type region and a breakdown voltage;

FIG. 8 shows a simulation result indicating a relation between a charge amount per unit area of the N-type region and a breakdown voltage;

FIG. 9 shows a simulation result indicating a relation between a charge amount per unit area of the N-type region and an output capacitance loss;

FIG. 10 shows another simulation result indicating a relation between a charge amount per unit area of the N-type region and an output capacitance loss;

FIG. 11 is a sectional view of a semiconductor device according to a second embodiment of the present disclosure;

FIG. 12A is a view showing a state of depletion layers in the semiconductor device shown in FIG. 11;

FIG. 12B is a view showing another state of the depletion layers in the semiconductor device shown in FIG. 11;

FIG. 12C is a view showing still another state of the depletion layers in the semiconductor device shown in FIG. 11;

FIG. 12D is a view showing still another state of the depletion layers in the semiconductor device shown in FIG. 11;

FIG. 13 shows a simulation result indicating a relation between a drain-source voltage and a drain-source capacitance;

FIG. 14 is a sectional view of a semiconductor device according to a third embodiment of the present disclosure;

FIG. 15 is a view showing a relation between a proportion of a width of an N-type region to a width of a P-type column region and an output capacitance loss;

FIG. 16 is a sectional view of a semiconductor device in which a width of the N-type region is 100% or more of a width of the P-type column region;

FIG. 17 is a view showing a relation between a proportion of a width of the N-type region in relation to a width of the P-type column region and an output capacitance loss;

FIG. 18 shows a simulation result indicating a relation between a variation in the N-type region and an output capacitance loss;

FIG. 19 shows a simulation result indicating a relation between a variation in the N-type region and a breakdown voltage;

FIG. 20 is a top view of an N-type column region, a P-type column region, and an N-type region according to a fourth embodiment of the present disclosure;

FIG. 21 shows a simulation result indicating a relation between a proportion of a length of the N-type region in a longitudinal direction in relation to a length of the P-type column region in the longitudinal direction and an output capacitance loss;

FIG. 22 is a sectional view of a semiconductor device according to a fifth embodiment of the present disclosure;

FIG. 23 shows a simulation result indicating a relation between a drain-source voltage and a drain-source capacitance;

FIG. 24 is a sectional view of a semiconductor device according to a sixth embodiment of the present disclosure;

FIG. 25 is a simulation result indicating a relation between a drain-source voltage and a drain-source capacitance;

FIG. 26 is a sectional view of a semiconductor device according to another embodiment of the present disclosure;

FIG. 27A is a top view of an N-type column region, a P-type column region, and an N-type region according to still another embodiment of the present disclosure;

FIG. 27B is a top view of an N-type column region, a P-type column region, and an N-type region according to still another embodiment of the present disclosure;

FIG. 27C is a top view of an N-type column region, a P-type column region, and an N-type region according to still another embodiment of the present disclosure; and

FIG. 27D is a top view of an N-type column region, a P-type column region, and an N-type region according to still another embodiment of the present disclosure.

### DETAILED DESCRIPTION

Hereinafter, embodiments of the present disclosure will be described with reference to the drawings. In respective embodiments below, descriptions will be given by labeling same or equivalent portions with same reference numerals.

### First Embodiment

A first embodiment of the present disclosure will be described with reference to the drawings. The present embodiment will be described in regard to a semiconductor device provided with a trench-gate vertical MOSFET (Metal-Oxide-Semiconductor Field-Effect Transistor) as an example.

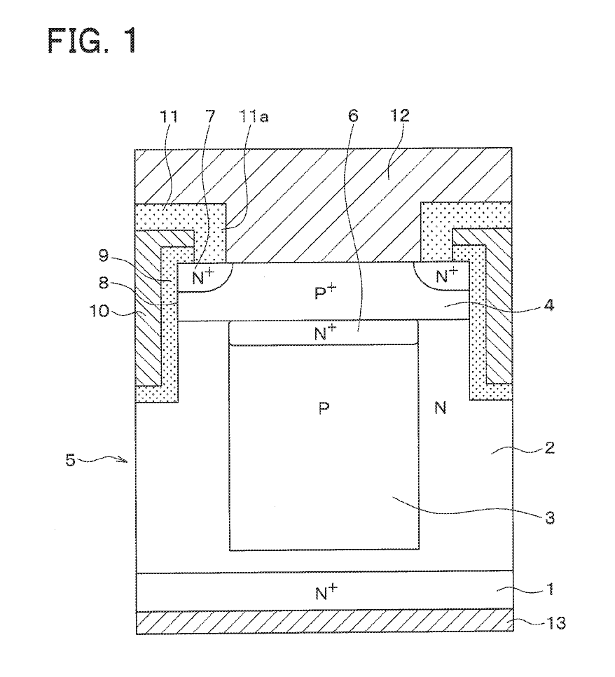

As is shown in FIG. 1, the semiconductor device includes an N⁺-type drain layer 1 formed of a silicon substrate or the like, on which an N-type column region 2 as a drift region and a P-type column region 3 are provided to form an SJ structure. In the present embodiment, the N-type column region 2 and the P-type column region 3 are provided to extend in one direction parallel to a planar direction of the drain layer 1 (a direction perpendicular to a sheet surface of FIG. 1) and also aligned repetitively in a direction orthogonal to the one direction (a right-left direction on the sheet surface of FIG. 1). A semiconductor substrate 5 is formed by providing a P⁺-type base layer 4 on the SJ structure.

Given that an alignment direction of the N-type column regions 2 and the P-type column regions 3 is a width direction, then the N-type column regions 2 and the P-type column regions 3 have equal column widths and equal impurity concentration. Although the column width and the impurity concentration are not particularly limited, the column width is 3 μm (column pitch is 6 μm) and impurity concentration is 8.0×10¹⁵ cm⁻³ in the present embodiment. The N-type column regions 2, the P-type column regions 3, and the base layer 4 are made of silicon or the like.

An N-type region 6 is provided to the P-type column region 3. In the present embodiment, the N-type region 6 is provided on an entire surface of a surface-layer portion of the P-type column region 3. In FIG. 1, only one P-type column region 3 is shown. It should be appreciated, however, that multiple P-type column regions 3 are provided in practice. Also, the N-type region 6 is provided to any P-type column region 3. That is to say, the N-type column region 6 may be provided to every one of the multiple P-type column regions 3 or only one of the multiple P-type column regions 3. In short, the number of the P-type column regions 3 provided with the N-type region 6 can be changed as needed. A specific charge amount per unit area of the N-type region 6 will be described below.

An N⁺-type source layer 7 having a higher impurity concentration than the N-type column region 2 is provided to a surface-layer portion of the base layer 4. Although an illustration is omitted herein, a P⁺-type contact layer having a higher impurity concentration than the base layer 4 may be provided to the surface-layer portion of the base layer 4.

A trench 8 penetrating through the source layer 7 and the base layer 4 to the N-type column region 2 is provided. In the present embodiment, multiple trenches 8 have a length in an extending direction of the N-type column regions 2 and the P-type column regions 3 (the direction perpendicular to the sheet surface of FIG. 1) as a longitudinal direction, and are aligned side by side at regular intervals.

A gate insulating film 9 is provided so as to cover a surface of the trench 8 and a gate electrode 10 made of doped poly-Si or the like is provided on a surface of the gate insulating film 9 so as to fill up the trench 8. A trench-gate structure is thus formed.

An inter-layer insulating film 11 is provided on the trench-gate structure and the base layer 4 so as to cover the gate electrode 10. A source electrode 12 is provided on the inter-layer insulating film 11. The source electrode 12 is electrically connected to the source layer 7 and the base layer 4 (contact layer) via contact holes 11a made in the inter-layer insulating film 11. On the other hand, a drain electrode 13 to be electrically connected to the drain layer 1 is provided to the drain layer 1 on an opposite side to the SJ structure.

The configuration of the semiconductor device of the present embodiment has been described above. In the present embodiment, the N-type corresponds to a first conductivity type and the P-type corresponds to a second conductivity type. The drain layer 1 corresponds to a semiconductor layer, the N-type column region 2 corresponds to a first conductivity type column region, the P-type column region 3 corresponds to a second conductivity type column region, the base layer 4 corresponds to a second conductivity type layer, and the N-type region 6 corresponds to a first conductivity type region. The source electrode 12 corresponds to a second electrode and the drain electrode 13 corresponds to a first electrode.

In the semiconductor device configured as above, when a gate voltage is not applied to the gate electrode 10, basically, a channel is not formed in the base layer 4 in a portion in contact with the trench 8. Meanwhile, when a predetermined gate voltage is applied to the gate electrode 10, a channel of an inverted conductivity type is formed in the base layer 4 in the portion in contact with the trench 8. A current thus flows between the source electrode 12 and the drain electrode 13 through the channel.

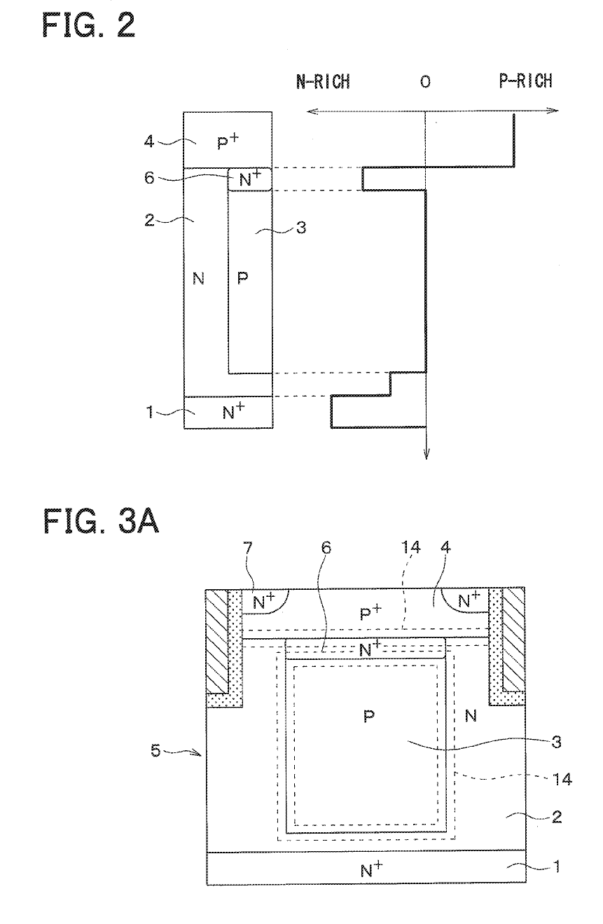

A charge balance of the semiconductor substrate 5 in the semiconductor device of the present embodiment will now be described with reference to FIG. 2.

As has been described, the N-type column regions 2 and the P-type column regions 3 have equal column widths and equal impurity concentration. Hence, as is shown in FIG. 2, surplus concentration of the semiconductor substrate 5 in a thickness (depth) direction is P-rich in a portion where the base layer 4 is provided. On the other hand, the surplus concentration is N-rich in the SJ structure in a portion where the N-type region 6 is provided, and charges are balanced in the SJ structure in a portion where the N-type region 6 is not provided. The surplus concentration is N-rich in a portion where the drain layer 1 is provided.

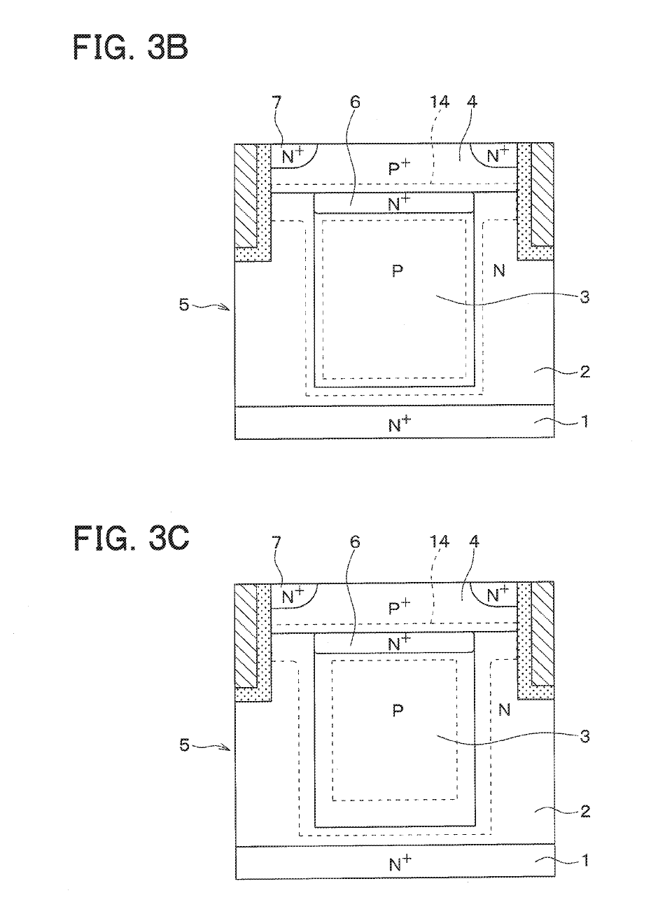

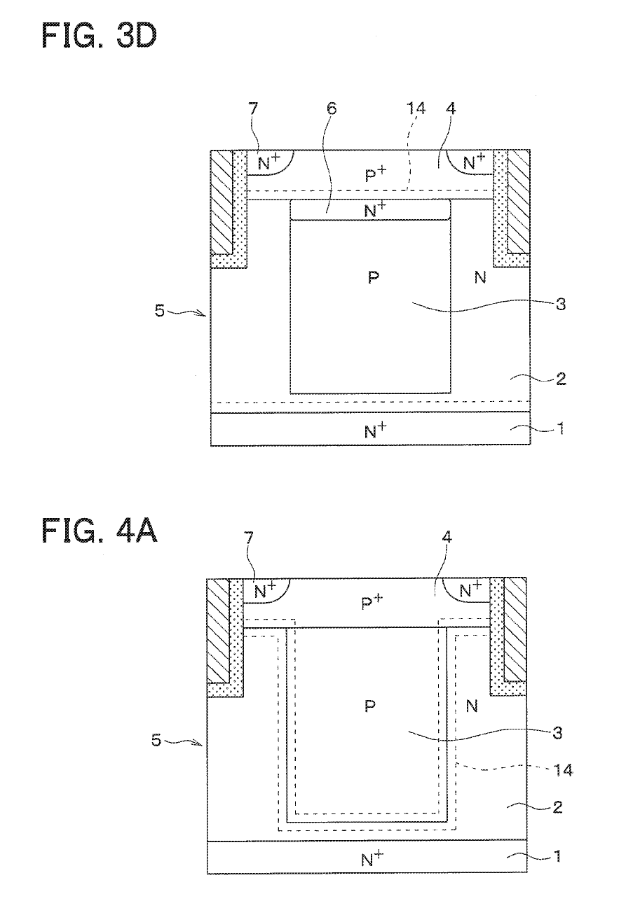

In the semiconductor device configured as above, when a drain-source voltage is 0 V (OFF state), as is shown in FIG. 3A, depletion layers 14 are formed on PN junction surfaces between the base layer 4 and the N-type column region 2 as well as the base layer 4 and the N-type region 6, on a PN junction surface between the N-type column region 2 and the P-type column region 3, and on a PN junction surface between the P-type column region 3 and the N-type region 6. That is to say, in the present embodiment, the P-type column region 3 is in a floating state when a drain-source voltage is 0 V, because the base layer 4 and the P-type column region 3 are divided by the depletion layers 14.

Herein, for example, the depletion layer 14 formed on the PN junction surface between the base layer 4 and the N-type column region 2 and the depletion layer 14 formed on the PN junction surface between the base layer 4 and the N-type region 6 connect to each other. Also, the depletion layer 14 formed on the PN junction surface between the N-type column region 2 and the P-type column region 3 and the depletion layer 14 formed on the PN junction surface between the P-type column region 3 and the N-type region 6 connect to each other.

When a low voltage is applied between the drain and the source, the base layer 4 comes to have a source potential and the N-type column region 2 and the N-type region 6 come to have a drain potential. Hence, as is shown in FIG. 3B, the depletion layer 14 formed on the PN junction surfaces between the base layer 4 and the N-type column region 2 as well as the base layer 4 and the N-type region 6 expands and the N-type region 6 is covered with the expanded depletion layer 14. Eventually, the depletion layer 14 formed on the PN junction surfaces between the base layer 4 and the N-type column region 2 as well as the base layer 4 and the N-type region 6 and the depletion layer 14 formed on the PN junction surface between the N-type column region 2 and the P-type column region 3 unite with each other. Meanwhile, the depletion layer 14 formed on the PN junction surface between the N-type column region 2 and the P-type column region 3 hardly varies in a state shown in FIG. 3B.

When the drain-source voltage becomes higher, as is shown in FIG. 3C, the depletion layer 14 formed on the PN junction surface between the N-type column region 2 and the P-type column region 3 expands. Herein, the P-type column region 3 in the floating state changes to a potential state higher than the source potential and no longer has a potential equal to the source potential. When the drain-source voltage becomes further higher, as is shown in FIG. 3D, the expanded depletion layers 14 fully cover the P-type column region 3. The semiconductor device is thus completely depleted.

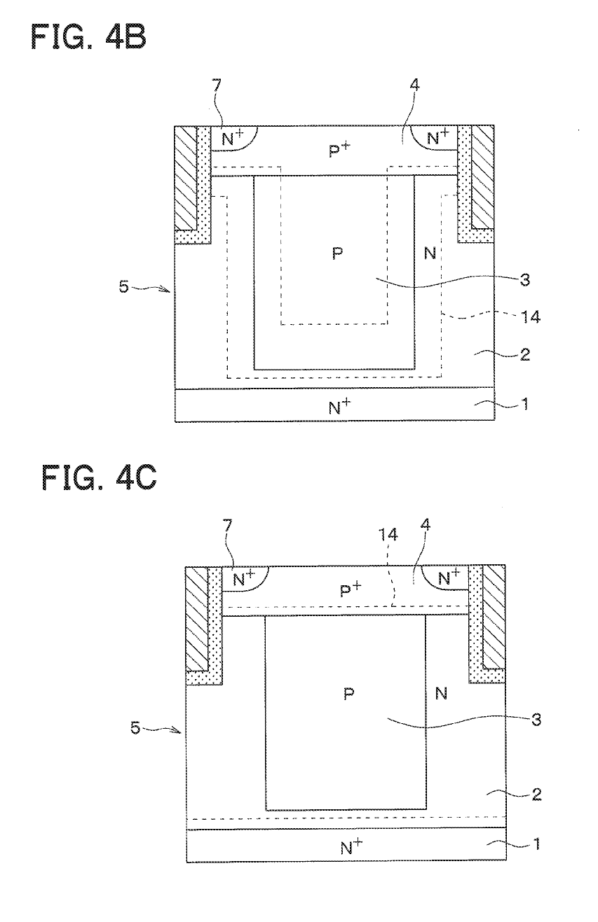

On the contrary, in a comparative example which is a semiconductor device in the related art having no N-type region 6 in the P-type column region 3, when a drain-source voltage is 0 V (OFF state), as is shown in FIG. 4A, the depletion layer 14 is formed along the PN junction surface between the N-type column region 2 and the P-type column region 3. Herein, the P-type column region 3 is equipotential with the base layer 4. When a low voltage is applied between the drain and the source, as is shown in FIG. 4B, the depletion layer 14 formed along the PN junction surface between the N-type column region 2 and the P-type column region 3 expands. When the drain-source voltage becomes further higher, as is shown in FIG. 4C, the semiconductor device is completely depleted as the expanded depletion layer 14 fully covers the P-type column region 3.

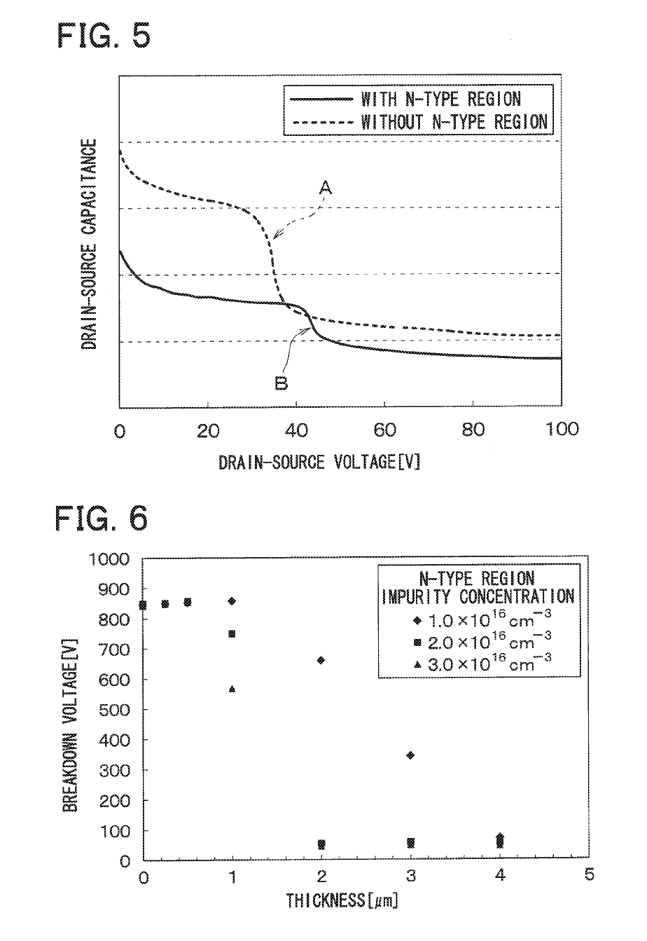

As has been described, in the semiconductor device of the present embodiment, the P-type column region 3 can be in a floating state in an OFF state. Consequently, as is shown in FIG. 5, a drain-source capacitance when a drain-source voltage is 0 V (OFF) can be smaller. Hence, an output capacitance loss can be reduced. In the present embodiment, a case where a drain-source voltage is 0 V corresponds to a case where a voltage between the first electrode and the second electrode is a predetermined voltage.

Because a drain-source capacitance when a drain-source voltage is 0 V can be smaller, as are indicated by arrows A and B in FIG. 5, a variation in drain-source capacitance when the semiconductor device is completely depleted can be lessened. Hence, occurrences of switching noises and a gate malfunction can be restricted. FIG. 5 shows a simulation result when a gate-source voltage is 0 V and a frequency is 1 MHz.

In the semiconductor device configured as above, a charge amount of the N-type region 6 has an influence on a breakdown voltage. That is to say, as is shown in FIG. 6, a breakdown voltage decreases as the thickness of the N-type region 6 increases. More specifically, in a case where the impurity concentration of the N-type region 6 is 1.0×10¹⁶ cm⁻³, a breakdown voltage starts decreasing when the thickness of the N-type region 6 exceeds 1 μm. In cases where the impurity concentration of the N-type region 6 is 2.0×10¹⁶ cm⁻³ and 3.0×10¹⁶ cm⁻³, a breakdown voltage starts decreasing when the thickness of the N-type region 6 exceeds 0.6 μm.

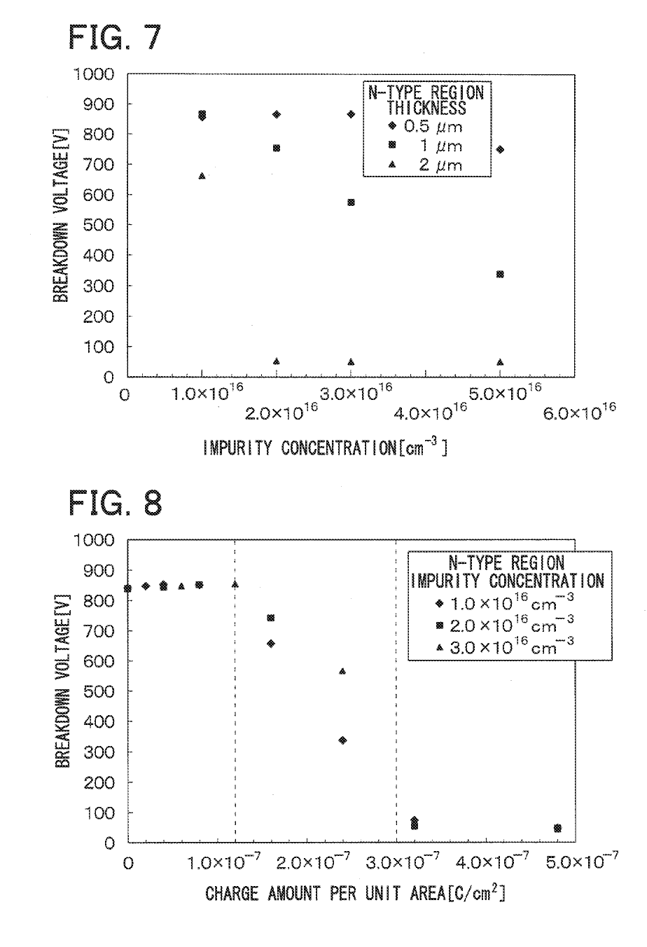

Also, as is shown in FIG. 7, a breakdown voltage decreases as impurity concentration of the N-type region 6 increases. More specifically, in a case where the thickness of the N-type region 6 is 0.5 μm, a breakdown voltage starts decreasing when the impurity concentration becomes higher than 3.0×10¹⁶ cm⁻³. In cases where the thickness of the N-type region 6 is 1 μm and 2 μm, a breakdown voltage starts decreasing when the impurity concentration becomes higher than 1.0×10¹⁶ cm⁻³.

In the manner as above, a charge amount (thickness and impurity concentration) of the N-type region 6 has an influence on a breakdown voltage. Assumed that a charge amount per unit area of the N-type region 6 be defined by impurity concentration×thickness×elementary charge. Then, a relation between a charge amount per unit area and a breakdown voltage can be described as follows. That is, as is shown in FIG. 8, a breakdown voltage starts decreasing when a charge amount per unit area of the N-type region 6 becomes larger than 1.2×10⁻⁷ C/cm². A breakdown voltage hardly varies when a charge amount per unit area becomes larger than 3.0×10⁻⁷ C/cm². Herein, a reason that a breakdown voltage hardly varies when a charge amount per unit area becomes larger than 3.0×10⁻⁷ C/cm² is because a charge amount per unit area is too large for the N-type region 6 to be depleted and the depletion layer 14 formed on the PN junction surface between the base layer 4 and the N-type region 6 fails to reach the P-type column region 3, thereby causing a breakdown voltage to decrease to a maximum extent.

FIG. 8 shows cases where the impurity concentration of the N-type region 6 is 1.0 to 3.0×10¹⁶ cm⁻³. It should be noted, however, that even when the impurity concentration of the N-type region 6 varies, a charge amount per unit area at which a breakdown voltage starts decreasing and a charge amount per unit area at which a breakdown voltage becomes a minimum hardly vary.

Hence, a charge amount per unit area of the N-type region 6 is set to 3.0×10⁻⁷ C/cm² or lower and more preferably set to 1.2×10⁻⁷ C/cm² or lower.

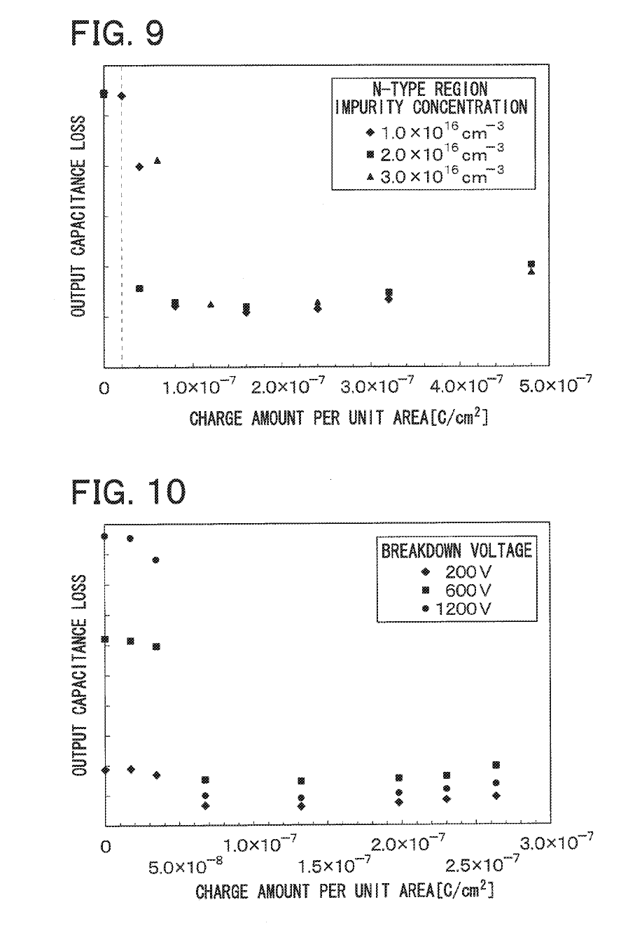

When a charge amount per unit area of the N-type region 6 is too small, the P-type column region 3 comes to have source potential because the N-type region 6 is completely depleted due to built-in potential even when a drain-source voltage is 0 V. That is to say, when a charge amount per unit area of the N-type region 6 is too small, a region that is not depleted, that is, a non-depletion layer region no longer exists in the N-type region 6 even when a drain-source voltage is 0 V and the P-type column region 3 is not changed to a floating state. Hence, even when the N-type region 6 is provided, an output capacitance loss is little reduced. To eliminate such an inconvenience, the N-type region 6 is set to a charge amount per unit area with which a non-depletion layer region exists when a drain-source voltage is 0 V. More specifically, as is shown in FIG. 9, because an output capacitance loss is reduced when a charge amount per unit area of the N-type region 6 is 2.0×10⁻⁸ C/cm² or higher, a charge amount per unit area of the N-type region 6 is set to 2.0×10⁻⁸ C/cm² or higher.

FIG. 9 shows a case where impurity concentration of the N-type region 6 is 1.0 to 3.0×10¹⁶ cm⁻³. It should be noted, however, that a charge amount per unit area at which an output capacitance loss starts decreasing hardly varies even when the impurity concentration of the N-type region 6 varies. FIG. 9 shows a simulation result when a drain-source voltage is 400 V.

For the reasons described above, a charge amount per unit area of the N-type region 6 of the present embodiment is set to 2.0×10⁻⁸ C/cm² or higher and 3.0×10⁻⁷ C/cm² or lower.

In the semiconductor device configured as above, a depth of the N-type column region 2 and the P-type column region 3 (thickness of the semiconductor substrate 5) can be changed suitably according to a required breakdown voltage (purpose of use). However, as is shown in FIG. 10, an output capacitance loss is reduced when a charge amount per unit area of the N-type region 6 is increased to 2.0×10⁻⁸ C/cm² or higher independently of a required breakdown voltage. In short, a charge amount per unit area of the N-type region 6 does not depend on a depth of the N-type column region 2 and the P-type column region 3.

As has been described, in the present embodiment, because the N-type region 6 is provided to the P-type column region 3, the P-type column region 3 can be in a floating state when a drain-source voltage is 0 V. Consequently, a drain-source capacitance can be smaller and hence an output capacitance loss can be reduced.

Because a drain-source capacitance when a drain-source voltage is 0 V can be smaller, a variation in drain-source capacitance when the semiconductor device is completely depleted can be lessened. Occurrences of switching noises and a gate malfunction can be thus restricted.

Because the N-type region 6 is provided to the P-type column region 3, the N-type region 6 serves as a barrier when a diode operation changes from an ON state to an OFF state and carriers within the N-type column region 2 and the P-type column region 3 are extracted from the source electrode 12 through the P-type column region 3. Hence, the semiconductor device has soft recovery by which carriers are moderately extracted into the source electrode 12. Hence, an increase in recovery noises and a surge voltage can be restricted.

In addition, a charge amount per unit area of the N-type region 6 is set to 2.0×10⁻⁸ C/cm² or higher. Hence, an effect on an output capacitance loss can be obtained in a reliable manner.

Further, a charge amount per unit area of the N-type region 6 is set to 3.0×10⁻⁷ C/cm² or lower. Hence, a decrease in a breakdown voltage can be restricted.

### Second Embodiment

A second embodiment of the present disclosure will be described. In contrast to the first embodiment above, an N-type region 6 is provided to a base layer 4 in the present embodiment. Because the present embodiment is same as the first embodiment above other than the above difference, a repetitive description is omitted herein.

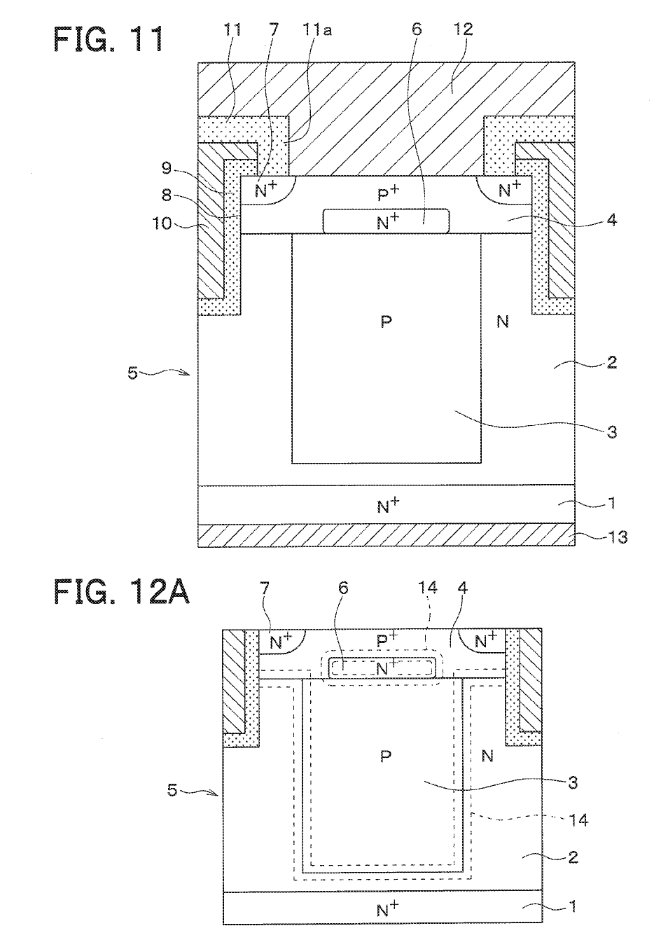

In the present embodiment, as is shown in FIG. 11, the N-type region 6 is provided to the base layer 4 in a portion located on a P-type column region 3. Herein, the N-type region 6 has a width (a length in a right-left direction on a sheet surface of FIG. 11) of 2 μm, a thickness of 1 μm, and impurity concentration of 2.0×10¹⁶ cm⁻³.

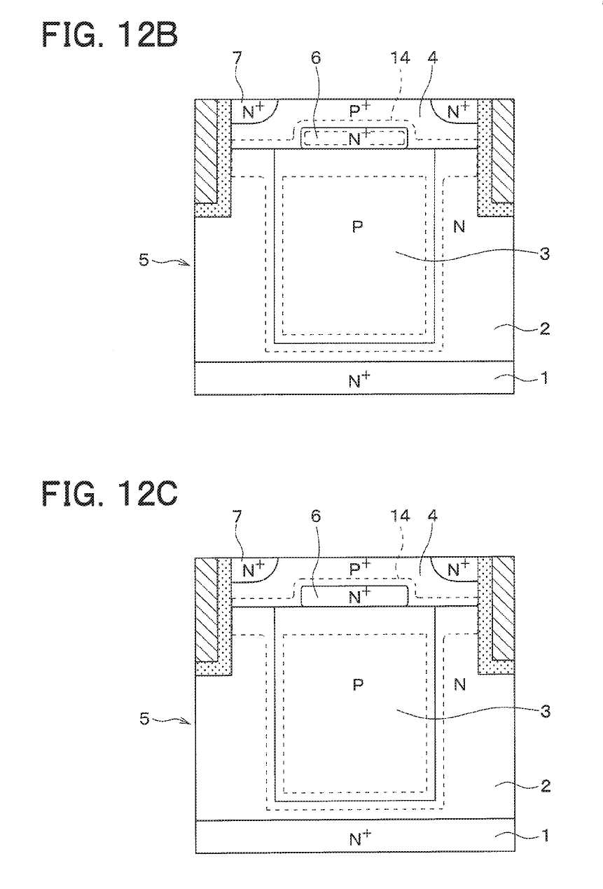

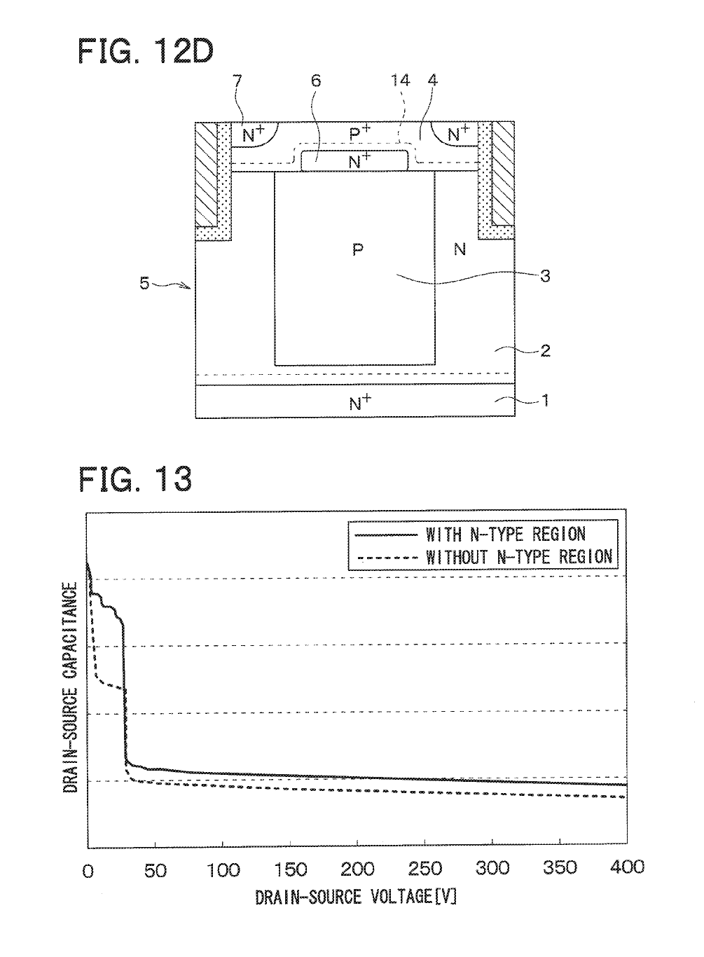

In the semiconductor device configured as above, when a drain-source voltage is 0 V (OFF state), as is shown in FIG. 12A, a depletion layer 14 formed on PN junction surfaces between an N-type column region 2 and the P-type column region 3 as well as the N-type column region 2 and the base layer 4 and a depletion layer 14 formed on PN junction surfaces between the N-type region 6 and the P-type column region 3 as well as the N-type region 6 and the base layer 4 do not connect to each other. In short, the P-type column region 3 is equipotential with the base layer 4. When a predetermined voltage is applied between the drain and the source, as is shown in FIG. 12B, the depletion layer 14 formed on the PN junction surface between the N-type column region 2 and the P-type column region 3 as well as the N-type column region 2 and the base layer 4 and the depletion layer 14 formed on the PN junction surfaces between the N-type region 6 and the P-type column region 3 as well as the N-type region 6 and the base layer 4 connect to each other. Hence, the base layer 4 and the P-type column region 3 are divided and the P-type column region 3 is changed to a floating state.

When a drain-source voltage becomes higher, as is shown in FIG. 12C, the N-type region 6 is covered with the connected depletion layers 14. When a drain-source voltage becomes further higher, as is shown in FIG. 12D, the connected depletion layers 14 fully cover the P-type column region 3 and the semiconductor device is completely depleted.

According to the configuration as above, as is shown in FIG. 13, when a drain-source voltage is 0 V, because the P-type column region 3 is equipotential with the base layer 4, a drain-source capacitance is same as a drain-source capacitance in a semiconductor device in the related art. However, when a predetermined voltage is applied between the drain and the source, the depletion layer 14 formed on the PN junction surfaces between the N-type column region 2 and the P-type column region 3 as well as the N-type column region 2 and the base layer 4 and the depletion layer 14 formed on the PN junction surfaces between the N-type region 6 and the P-type column region 3 as well as the N-type region 6 and the base layer 4 connect to each other. Consequently, the P-column region 3 is changed to a floating state (see FIG. 12B). In such a state, a drain-source capacitance can be smaller and hence an output capacitance loss can be reduced. FIG. 13 shows a simulation result when a gate-source voltage is 0 V and a frequency is 1 MHz.

By providing the N-type region 6 to the base layer 4, electric field concentration occurring in the P-type column region 3 can be restricted in comparison with a case where the N-type region 6 is provided to the P-type column region 3. Consequently, a breakdown voltage can be enhanced.

In the present embodiment, when a drain-source voltage is 0 V, the P-type column region 3 is equipotential with the base layer 4. Hence, an increase in ON resistance can be restricted.

Even when the N-type region 6 is provided to the base layer 4 as above, an effect on an output capacitance loss can be obtained in a reliable manner by setting a charge amount per unit area to 2.0×10⁻⁸ C/cm² or higher as in the first embodiment above. In addition, by setting a charge amount per unit area to 3.0×10⁻⁷ C/cm² or lower, a decrease in a breakdown voltage can be restricted.

The above has described a case where the N-type region 6 is provided to the base layer 4 and when a drain-source voltage is 0 V (OFF state), the depletion layer 14 formed on the PN junction surfaces between the N-type column region 2 and the P-type column region 3 as well as the N-type column region 2 and the base layer 4 and the depletion layer 14 formed on the PN junction surfaces between the N-type region 6 and the P-type column region 3 as well as the N-type region 6 and the base layer 4 do not connect to each other. However, even in a case where the N-type region 6 is provided to the base layer 4, by adequately adjusting a width of the N-type region 6 or the like, the depletion layer 14 formed on the PN junction surfaces between the N-type column region 2 and the P-type column region 3 as well as the N-type column region 2 and the base layer 4 and the depletion layer 14 formed on the PN junction surfaces between the N-type region 6 and the P-type column region 3 as well as the N-type region 6 and the base layer 4 may connect to each other when a drain-source voltage is 0 V (OFF state). In such a case, a drain-source capacitance when a drain-source voltage is 0 V (OFF state) can be smaller as in the first embodiment above. Hence, occurrences of switching noises and a gate malfunction can be restricted.

### Third Embodiment

A third embodiment of the present disclosure will be described. In the present embodiment, a width of an N-type region 6 is changed from the width in the first embodiment above. Because the present embodiment is same as the first embodiment above other than the above difference, a repetitive description is omitted herein.

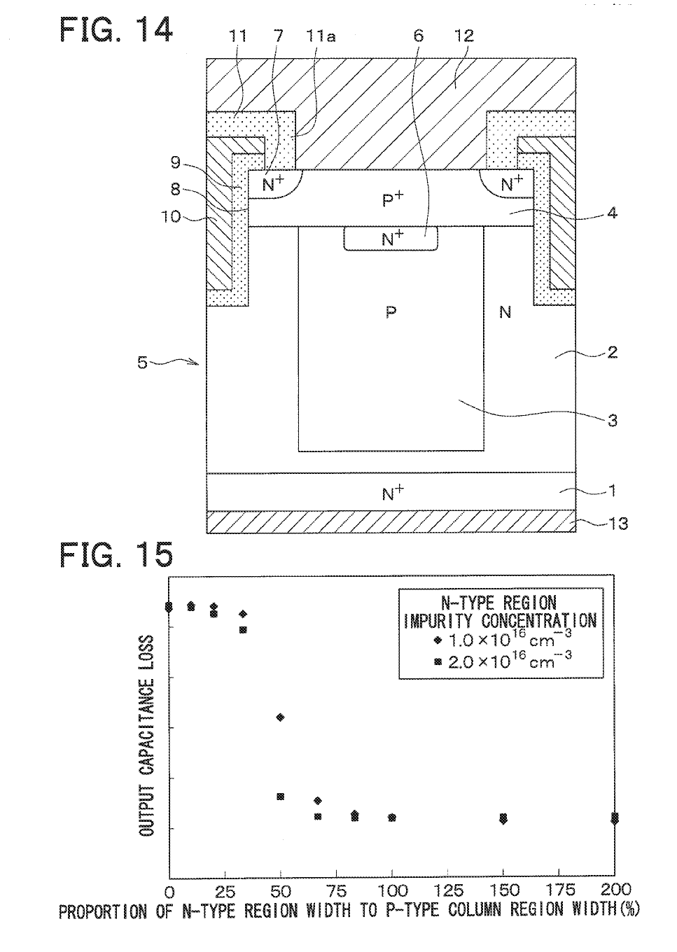

In the present embodiment, as is shown in FIG. 14, the N-type region 6 is not provided on an entire surface of a surface-layer portion of a P-type column region 3 and instead provided in a part of the surface-layer portion of the P-type column region 3. More specifically, the N-type region 6 has a width (a length in a right-left direction of a sheet surface of FIG. 14) of 1.5 μm and is provided in a center portion of the P-type column region 3 so that the center of the N-type region 6 coincides with the center of the P-type column region 3. In short, a width of the N-type region 6 is 50% of a width of the P-type column region 3. The P-type column region 3 connects to a base layer 4 and is therefore electrically connected to the base layer 4.

Even in the semiconductor device in which the N-type region 6 is not provided on an entire surface of the surface-layer portion of the P-type column region 3 as above, an output capacitance loss can be reduced (see FIG. 15) by allowing the P-type column region 3 to be in a floating state when a predetermined voltage is applied between a drain and a source, similarly to the second embodiment above.

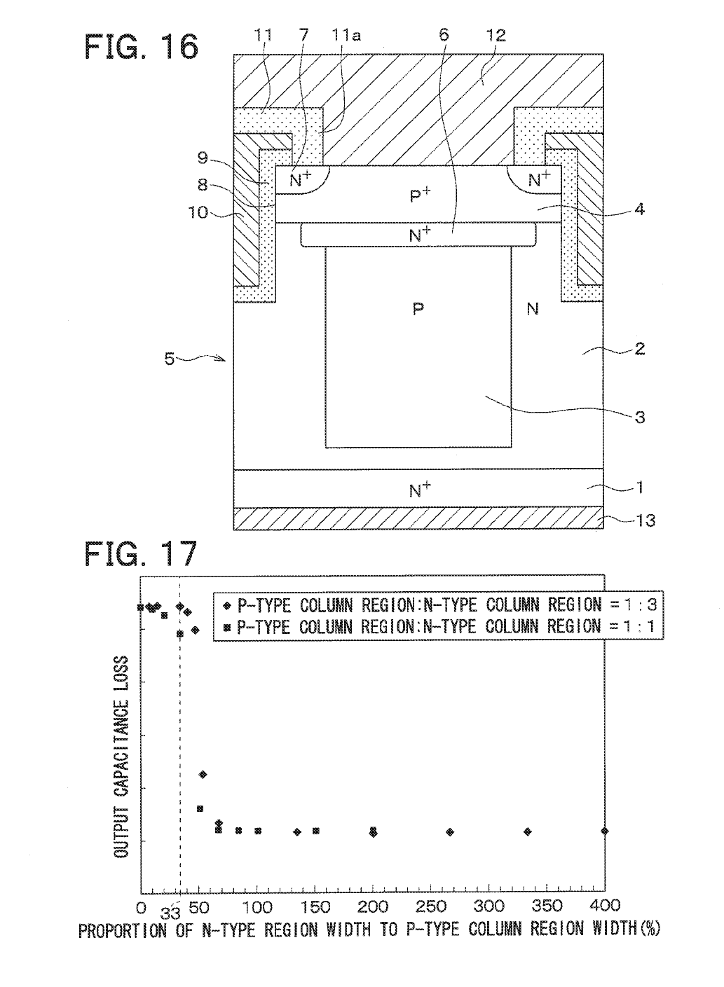

FIG. 15 shows a simulation result when the N-type region 6 has a thickness of 1 μm and impurity concentration of 1.0×10¹⁶ cm⁻³ and 2.0×10¹⁶ cm⁻³ and a drain-source voltage is 400 V. In FIG. 15, when a width of the N-type region 6 is 0% of a width of the P-type column region 3, it means that the N-type region 6 is not provided in the P-type column region 3. Also, in FIG. 15, when a width of the N-type region 6 is 100% or more of a width of the P-type column region 3, it means a case as shown FIG. 16 where the N-type region 6 is provided so as to protrude from the P-type column region 3 into the N-type column region 2. For example, in FIG. 15, when a width of the N-type region 6 is 200% of a width of the P-type column region 3, it is a state where the entire surfaces of the surface-layer portions of the N-type column region 2 and the P-type column region 3 are covered with the N-type region 6. In the case of a semiconductor device in which the entire surfaces of the surface-layer portions of the N-type column region 2 and the P-type column region 3 are covered with the N-type region 6 as above, the semiconductor device is fabricated by, for example, forming the N-type column region 2 and the P-type column region 3, forming the N-type region 6 on the entire surfaces of the N-type column region 2 and the P-type column region 3 on the opposite side to the drain layer 1 by ion implantation or heat treatment, and then forming a trench 8, a gate electrode 10 and so on. Alternatively, the semiconductor device as above may be fabricated by forming the N-type column region 2 and the P-type column region 3, forming the N-type region 6 on the entire surfaces of the N-type column region 2 and the P-type column region 3 on the opposite side to the drain layer 1 by ion implantation or heat treatment after the trench 8 is formed, and then forming a gate electrode 10 and so on. As is revealed from FIG. 15, an output capacitance loss can be reduced even when the N-type region 6 is provided so as to spread over the P-type column region 3 to the N-type column region 2.

In the present embodiment, the semiconductor device includes the N-type column region 2 and the P-type column region 3 having equal widths. However, in a case where a ratio of a width of the N-type column region 2 with respect to a width of the P-type column region 3 is 3 or less, it is preferable that a width of the N-type region 6 is 33% (0.33) or more of the width of the P-type column region 3 for a reason as follows. That is, as is shown in FIG. 17, because, in the case where a ratio of a width of the N-type column region 2 with respect to a width of the P-type column region 3 is 3 or less, an output capacitance loss can be reduced steeply when a width of the N-type region 6 is 33% or more of the width of the P-type column region 3. In a case where a width of the N-type column region 2 is equal to a width of the P-type column region 3, that is, in a case where a ratio of a width of the N-type column region 2 with respect to a width of the P-type column region 3 is 1, an output capacitance loss can be reduced steeply when a width of the N-type region 6 is 10% (0.1) or more of the width of the P-type column region 3.

Also in the present embodiment, similarly to the first embodiment, the number of the P-type column regions 3 provided with the N-type region 6 can be changed suitably, and it is sufficient for the P-type column region 3 provided with the N-type region 6 and the N-type region 6 have the relationship as described above. FIG. 17 shows a simulation result when the N-type region 6 has a thickness of 1 μm and impurity concentration of 2.0×10¹⁶ cm⁻³ and a drain-source voltage is 400 V.

Similarly to the second embodiment, because the P-type column region 3 is equipotential with the base layer 4, when a drain-source voltage is 0 V, an increase in ON resistance can be restricted.

It has described above about a case where the N-type region 6 is not provided on the entire surface of the surface-layer portion of the P-type column region 3, and the N-type region 6 is provided in the center portion of the P-type column region 3. However, centers of the N-type region 6 and the P-type column region 3 may be displaced from each other due to misalignment occurring when the N-type region 6 is formed.

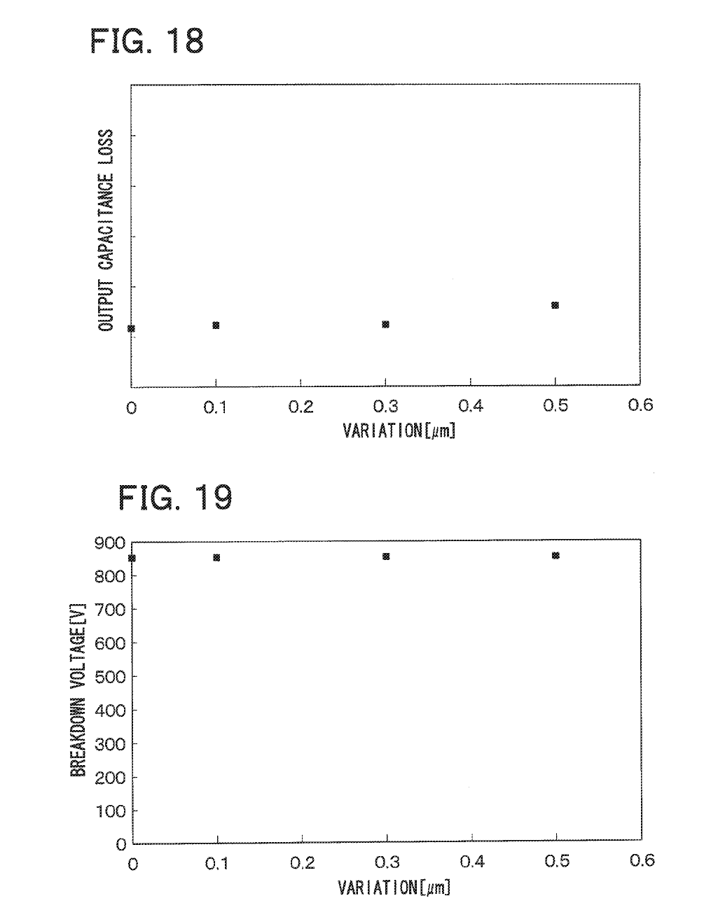

For example, displacement between the center of the P-type column region 3 and the center of the N-type region 6 is given as a variation. Then, as is shown in FIG. 18, even when the center of the N-type region 6 and the center of the P-type column region 3 are displaced, an output capacitance loss hardly varies. Likewise, as is shown in FIG. 19, even when the center of the N-type region 6 and the center of the P-type column region 3 are displaced, a breakdown voltage hardly varies.

FIG. 18 and FIG. 19 show simulation results when a thickness of the N-type region 6 is 1 μm, a width of the N-type region 6 is 1.5 μm (a width accounting for 50% of a width of the P-type column region 3) and impurity concentration is 2.0×10¹⁶ cm⁻³. In FIG. 18, a drain-source voltage is 400 V.

### Fourth Embodiment

A fourth embodiment of the present disclosure will be described. In the present embodiment, a length of an N-type region 6 in a longitudinal direction is changed from the length in the third embodiment above. Because the present embodiment is same as the third embodiment above other than the above difference, a repetitive description is omitted herein.

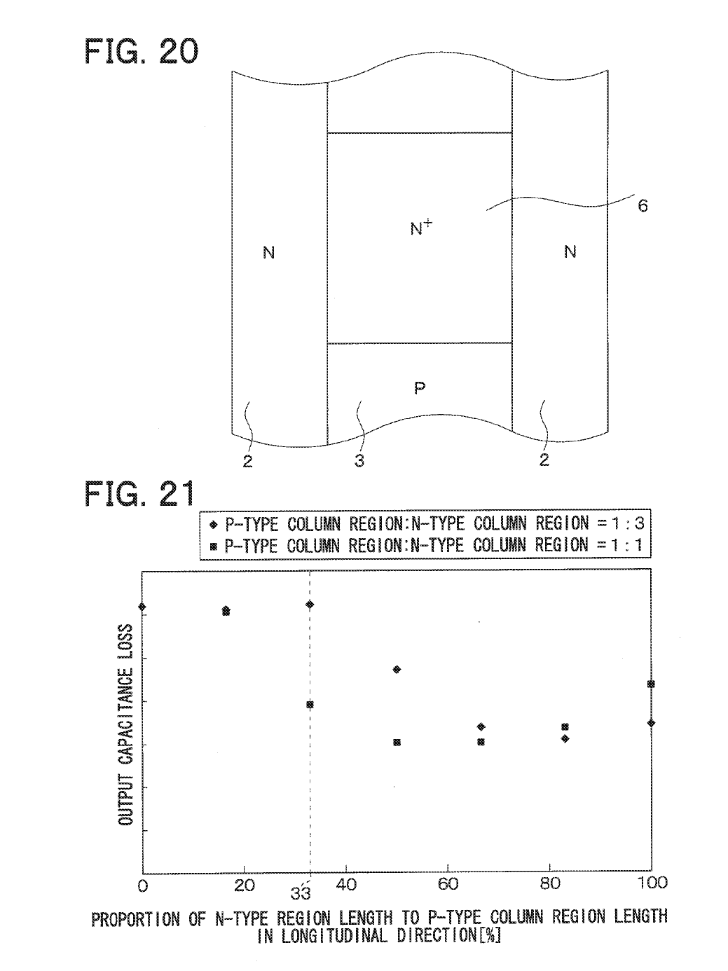

In the present embodiment, as is shown in FIG. 20, a width of the N-type region 6 is equal to a width of a P-type column region 3 whereas a length in the longitudinal direction (an extending direction of the P-type column region 3) is shorter than a length of the P-type column region 3 in the longitudinal direction. In the present embodiment, a center of the N-type region 6 in the longitudinal direction coincides with a center of the P-type column region 3 in the longitudinal direction and a length of the N-type region 6 in the longitudinal direction is 33% of a length of the P-type column region 3 in the longitudinal direction. The P-type column region 3 connects to a base layer 4 and is therefore electrically connected to the base layer 4. In the present embodiment, the longitudinal direction of an N-type column region 2 and the P-type column region 3 corresponds to one direction.

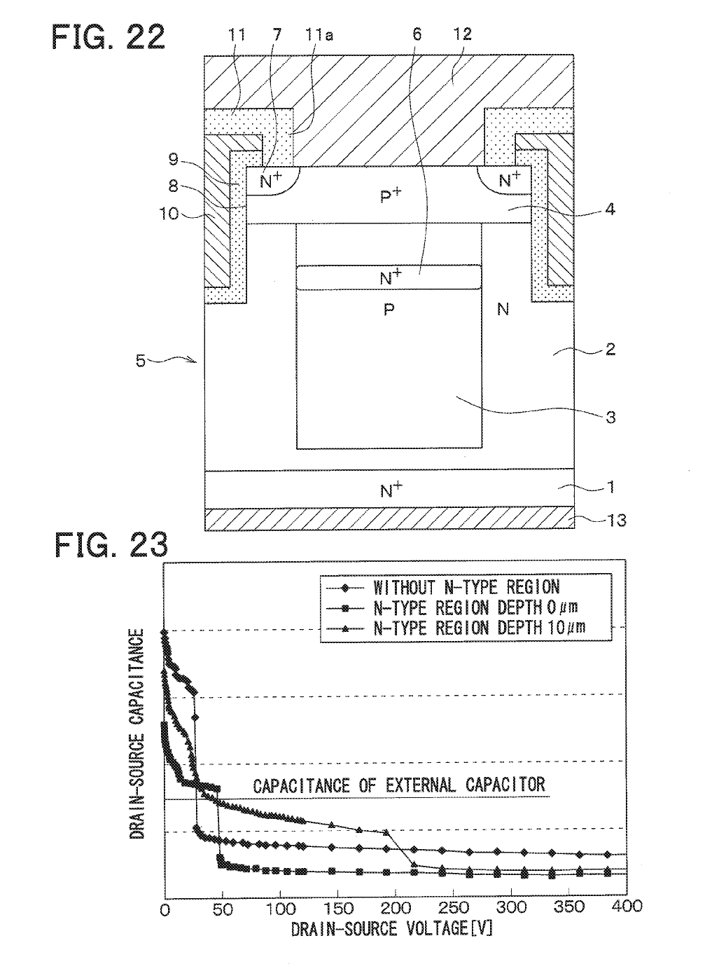

Even in the semiconductor device in which the length of the N-type region 6 in the longitudinal direction is shorter than the length of the P-type column region 3 in the longitudinal direction, an output capacitance loss can be reduced (see FIG. 21), similarly to the third embodiment above.

In the present embodiment, the semiconductor device includes the N-type column region 2 and the P-type column region 3 having equal widths. However, when a ratio of a width of the N-type column region 2 with respect to a width of the P-type column region 3 is 3 or less, it is preferable that a length of the N-type region 6 in the longitudinal direction is 33% (0.33) or more of a length of the P-type column region 3 in the longitudinal direction for a reason as follows. That is, as is shown in FIG. 21, in a case where a length of the N-type column region 2 in the longitudinal direction with respect to a length of the P-type column region 3 in the longitudinal direction is 3 or less, an output capacitance loss can be reduced steeply when a length of the N-type region 6 in the longitudinal direction is 33% or more of the length of the P-type column region 3 in the longitudinal direction. In a case where a width of the N-type column region 2 is equal to a width of the P-type column region 3, that is, in a case where a ratio of a width of the N-type column region 2 with respect to a width of the P-type column region 3 is 1, an output capacitance loss can be reduced steeply when a length of the N-type region 6 in the longitudinal direction is 18% (0.18) or more of a length of the P-type column region 3 in the longitudinal direction.

Also in the present embodiment, similarly to the first embodiment above, the number of the P-type column regions 3 provided with the N-type region 6 can be changed, and it is sufficient for the P-type column region 3 provided with the N-type region 6 and the N-type region 6 to have the relationship as described above. FIG. 21 shows a simulation result when the N-type region 6 has a thickness of 1 μm and impurity concentration of 3.0×10¹⁶ cm⁻³ and a drain-source voltage is 400 V. In FIG. 21, when a length of the N-type region 6 in the longitudinal direction is 0% of a length of the P-type column region 3 in the longitudinal direction, it means that the N-type region 6 is not provided to the P-type column region 3.

Also, as is shown in FIG. 21, in a case where a ratio of a width of the N-type column region 2 with respect to a width of the P-type column region 3 is 1, an output capacitance loss increases when a length of the N-type region 6 in the longitudinal direction is 50% or more of a length of the P-type column region 3 in the longitudinal direction for a reason as follows. That is, a charge amount is increased when a covered ratio of the N-type region 6 is increased and the N-type region 6 is completely depleted at a higher voltage value. Hence, it is preferable to change a ratio of a length of the N-type region 6 in the longitudinal direction with respect to a length of the P-type column region 3 in the longitudinal direction suitably according to a usage.

It has been described above about a case where the centers of the N-type region 6 and the P-type column region 3 coincide with each other. It should be appreciated, however, that the centers of the N-type region 6 and the P-type column region 3 may be displaced.

### Fifth Embodiment

A fifth embodiment of the present disclosure will be described. In the present embodiment, a portion where an N-type region 6 is provided is changed from the portion in the first embodiment above. Because the present embodiment is same as the first embodiment above other than the above difference, a repetitive description is omitted herein.

In the present embodiment, as is shown in FIG. 22, the N-type region 6 is provided between a surface-layer portion and a bottom portion in a P-type column region 3 in a depth direction. More specifically, the N-type region 6 is provided at a depth of 10 μm from an interface (PN junction surface) between the P-type column region 3 and a base layer 4.

By changing a location where the N-type region 6 is provided as above, a drain-source voltage at which a semiconductor device is completely depleted can be changed appropriately. Hence, a degree of freedom in connection conditions with an external device or the like can be increased.

That is to say, the semiconductor device as above is used at a same time with an external capacitor (snubber capacitor) as an external device adjusting a switching speed. However, noises readily occur when a portion in which a variance in drain-source capacitance is noticeable coincides with a capacitance of the external capacitor. In other words, as is shown in FIG. 23, when the N-type region 6 is not provided or when the N-type region 6 is provided to a surface-layer portion (a depth of the N-type region 6 is 0 μm), a portion in which a drain-source capacitance varies steeply (a portion where the semiconductor device is completely depleted) coincides with a capacitance of the external capacitor. Hence, noises readily occur. In contrast, when a depth of the N-type region 6 is 10 μm, a portion in which a drain-source capacitance varies moderately coincides with the capacitance of the external capacitor. Hence, an occurrence of noises can be restricted.

In FIG. 23, a depth of the N-type region 6 means a depth from an interface between the P-type column region 3 and the base layer 4. When a depth of the N-type region 6 is 0 μm, it means that the N-type region 6 is provided in the surface-layer portion of the P-type column region 3. FIG. 23 shows a simulation result when the N-type region 6 has a thickness of 1 μm and impurity concentration of 2.0×10¹⁶ cm⁻³.

### Sixth Embodiment

A sixth embodiment of the present disclosure will be described. In contrast to the fifth embodiment above, multiple N-type regions 6 are provided in the present embodiment. Because the present embodiment is same as the fifth embodiment above other than the above difference, a repetitive description is omitted herein.

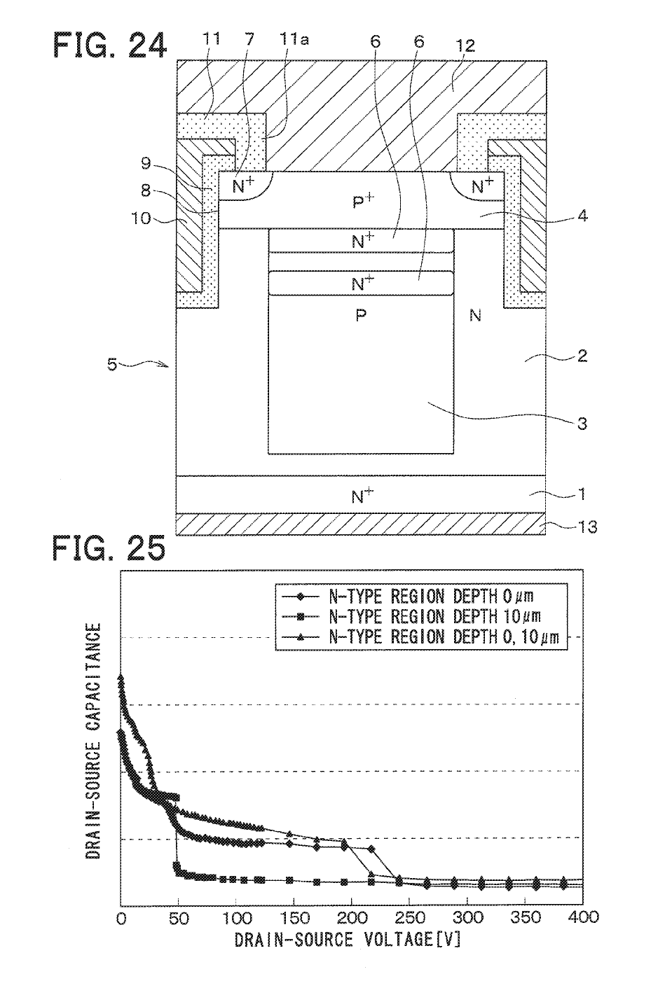

In the present embodiment, as is shown in FIG. 24, multiple N-type regions 6 are provided to a P-type column region 3. More specifically, the N-type regions 6 are provided in a surface-layer portion of the P-type column region 3 and in a portion at a depth of 10 μm from an interface between the P-type column region 3 and a base layer 4.

According to the configuration as above, as is shown in FIG. 25, a drain-source capacitance can be smaller because one N-type region 6 is provided in the surface-layer portion of the P-type column region 3. In addition, because another N-type region 6 is provided in a portion at a depth of 10 μm from the interface between the P-type column region 3 and the base layer 4, a drain-source voltage at which a semiconductor device is completely depleted can be changed.

In short, by providing the multiple N-type regions 6 to the P-type column region 3 in the depth direction, the semiconductor device has characteristics corresponding to the N-type regions 6 provided in the respective portions.

It has been described above about a case where the multiple N-type regions 6 are provided to the P-type column region 3. It should be appreciated, however, that a part of the multiple N-type regions 6 may be provided to the base layer 4.

### Other Embodiments

The present disclosure is not limited to the embodiments described above and can be changed as needed.

For example, the respective embodiments above have described a case where the first conductivity type is the N-type and the second conductivity type is the P-type. However, the configurations of the present disclosure are also applicable to a semiconductor device in which the first conductivity type is the P-type and the second conductivity type is the N-type. In short, the configurations of the present disclosure are also applicable to structures in which conductivity types of the respective portions described in the respective embodiments above are reversed.

For example, as an embodiment, a semiconductor device includes a semiconductor substrate 5 having a semiconductor layer 1 formed to be of a first conductivity type or a second conductivity type, a first conductivity type column region 2 provided on the semiconductor layer 1, a second conductivity type column region 3 provided on the semiconductor layer 1 and forming an SJ structure together with the first conductivity type column region 2, and a second conductivity type layer 4 provided on the first conductivity type column region 2 and the second conductivity type column region 3. The semiconductor device allows a current to flow between a first electrode 13 to be electrically connected to the semiconductor layer 1 and a second electrode 12 to be electrically connected to the second conductivity type layer 4.

The semiconductor device further includes a first conductivity type region 6 provided to at least one of the second conductivity type column region 3 and a second conductivity type layer 4 located on the second conductivity type column region 3. The first conductivity type region 6 has a non-depletion layer region when a voltage between the first electrode 13 and the second electrode 12 is 0. When a voltage between the first electrode 13 and the second electrode 12 is a predetermined voltage, a depletion layer 14 formed on interfaces between the first conductivity type column region 2 and the second conductivity type column region 3 as well as the first conductivity type column region 2 and the second conductivity type layer 4 and a depletion layer 14 formed between the first conductivity type region 6 and an interface of a region provided with the first conductivity type region 6 connect to each other.

According to the above configuration, the second conductivity type column region 3 can be in a floating state because the depletion layer 14 formed on the interfaces between the first conductivity type column region 2 and the second conductivity type column region 3 as well as the first conductivity type column region 2 and the second conductivity type layer 4 and the depletion layer 14 formed between the first conductivity type region 6 and the interface of the region provided with the first conductivity type region 6 connect to each other. Consequently, a drain-source capacitance can be smaller and hence an output capacitance loss can be reduced.

The first conductivity type region 6 is provided to at least one of the second conductivity type column region 3 and the second conductivity type layer 4 located on the second conductivity type column region 3. Hence, the first conductivity type region 6 serves as a barrier when a diode operation changes from an ON state to an OFF state and carriers within the first conductivity type column region 2 and the second conductivity type column region 3 are extracted from the second electrode 12 through the second conductivity type column region 3. Hence, the semiconductor device has soft recovery by which carriers are extracted moderately into the second electrode 12. Hence, an increase in recovery noises and a surge voltage can be restricted.

In the semiconductor device described above, when a voltage between the first electrode 13 and the second electrode 12 is 0, the depletion layer 14 formed on the interfaces between the first conductivity type column region 2 and the second conductivity type column region 3 as well as the first conductivity type column region 2 and the second conductivity type layer 4 and the depletion layer 14 formed between the first conductivity type region 6 and the interface of the region provided with the first conductivity type region 6 may connect to each other.

According to the configuration as above, a drain-source capacitance when a voltage between the first electrode 13 and the second electrode 12 is 0, that is, in an OFF state in which a current does not flow between the first electrode 13 and the second electrode 12, can be smaller. Consequently, a variation in drain-source capacitance when the semiconductor device is completely depleted can be lessened and hence occurrences of switching noises and a gate malfunction can be restricted.

In the semiconductor device configured as above, a charge amount per unit area of the first conductivity type region 6 may be set to 2.0×10⁻⁸ C/cm² or higher. In such a case, an output capacitance loss can be reduced markedly.

In the semiconductor device configured as above, a charge amount per unit area of the first conductivity type region may be set to 3.0×10⁻⁷ C/cm² or lower. In such a case, a decrease in a breakdown voltage can be restricted. Configurations of the semiconductor devices described in the respective embodiments above are mere examples and the present disclosure is not limited to the configurations described above. The semiconductor device may be of other configurations capable of realizing the configurations of the present disclosure. For example, the trench 8 may not be provided to extend along an alignment direction of the N-type column region 2 and the P-type column region 3. In short, the trench 8 may be provided to cut across the N-type column region 2 and the P-type column region 3.

A semiconductor element is not limited to a MOSFET and may be a diode or the like instead. Further, the semiconductor device may have a P-type collector layer instead of the N-type drain layer 1. In short, the semiconductor element may be an IGBT (Insulated Gate Bipolar transistor). Further, the gate structure may be of a planar type instead of a trench gate type. Also, the SJ structure may be provided like dots instead of a stripe manner described above. The semiconductor device may be a semiconductor device provided with a horizontal MOSFET. The drain layer 1 may be a gallium nitride substrate, a silicon carbide substrate, a diamond substrate or the like instead of the silicon substrate. The N-type column region 2, the P-type column region 3, and the base layer 4 may be made of gallium nitride, silicon carbide, diamond, or the like instead of silicon.

In the respective embodiments above, the semiconductor device may have the N-type region 6 provided to only one of neighboring P-type column regions 3. In short, the N-type region 6 may be provided in so-called a skipping structure.

In the respective embodiments above, multiple base layers 4 may be provided spaced apart from each other to the surface-layer portions of the N-type column region 2 and the P-type column region 3.

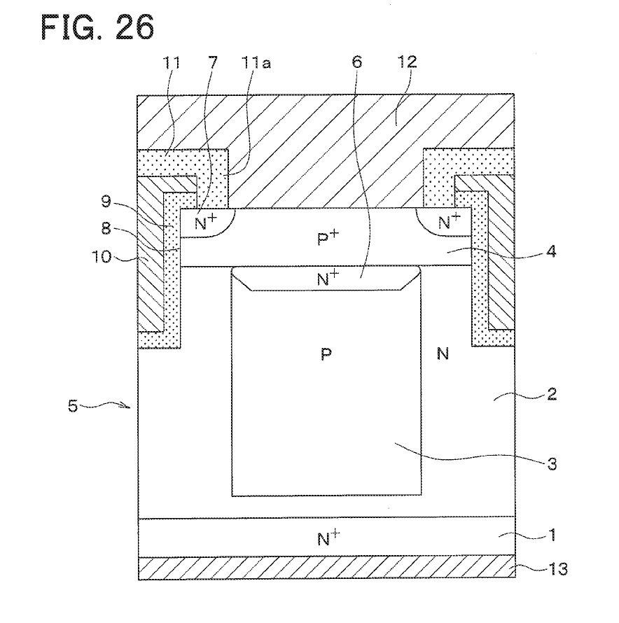

A shape of the N-type region 6 is not particularly limited. For example, as is shown in FIG. 26, the N-type region 6 may be tapered by becoming narrower in width along a depth direction of the P-type column region 3.

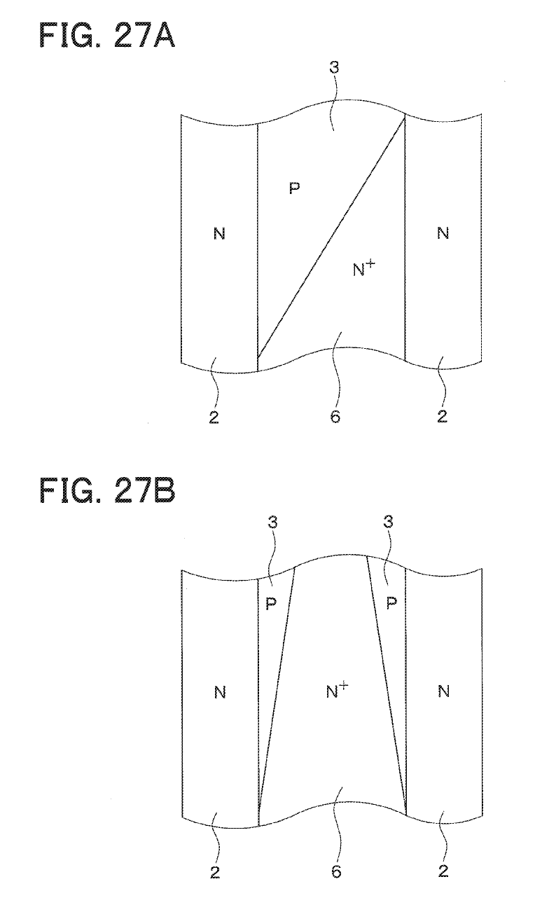

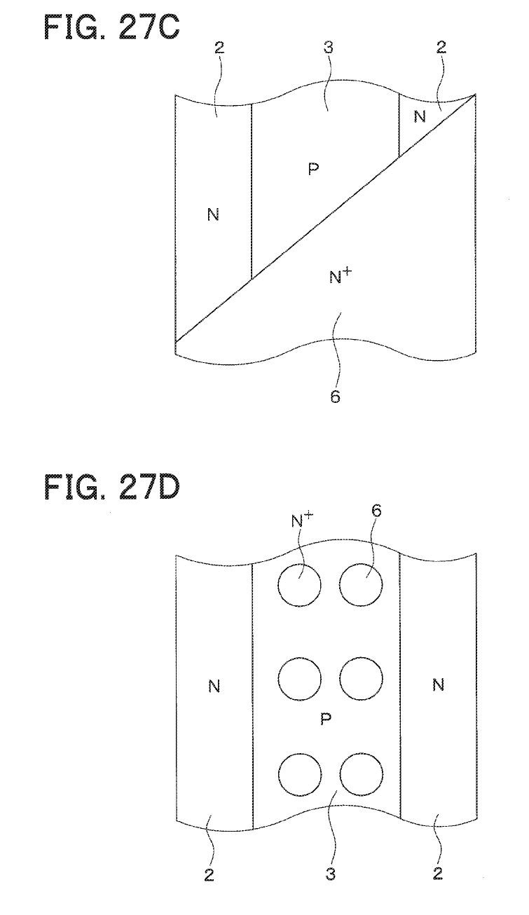

When the N-type region 6 is provided within the P-type column region 3, as is shown in FIG. 27A, the N-type region 6 may be tapered so as to move away from one of N-type column regions 2 neighboring in the longitudinal direction in a planar shape. Alternatively, when the N-type region 6 is provided within the P-type column region 3, as is shown in FIG. 27B, the N-type region 6 may be tapered so as to move away from both of N-type column regions 2 neighboring in the longitudinal direction in a planar shape. In addition, as is shown in FIG. 27C, the N-type region 6 may be tapered across the N-type column region 2 and the P-type column region 3 in a planar shape. Further, as is shown in FIG. 27D, the N-type region 6 may be provided in spots within the P-type column region 3 in a planar shape.

While only the selected exemplary embodiment and examples have been chosen to illustrate the present disclosure, it will be apparent to those skilled in the art from this disclosure that various changes and modifications can be made therein without departing from the scope of the disclosure as defined in the appended claims. Furthermore, the foregoing description of the exemplary embodiment and examples according to the present disclosure is provided for illustration only, and not for the purpose of limiting the disclosure as defined by the appended claims and their equivalents.

1. A semiconductor device comprising
a semiconductor substrate including:
a first conductivity type or second conductivity type semiconductor layer;
a first conductivity type column region provided on the semiconductor layer;
a second conductivity type column region provided on the semiconductor layer and forming a super-junction structure together with the first conductivity type column region; and
a second conductivity type layer provided on the first conductivity type column region and the second conductivity type column region,
wherein a current is allowed to flow between a first electrode electrically connected to the semiconductor layer and a second electrode electrically connected to the second conductivity type layer,
the semiconductor device further comprising a first conductivity type region provided to at least one of the second conductivity type column region and the second conductivity type layer located on the second conductivity type column region, wherein
the first conductivity type region has a non-depletion layer region when a voltage between the first electrode and the second electrode is 0 V, and
when the voltage between the first electrode and the second electrode is a predetermined voltage, a depletion layer formed on interfaces between the first conductivity type column region and the second conductivity type column region as well as the first conductivity type column region and the second conductivity type layer and a depletion layer formed between the first conductivity type region and an interface of a region provided with the first conductivity type region connect to each other.

2. The semiconductor device according to claim 1, wherein
when the voltage between the first electrode and the second electrode is 0 V, the depletion layer formed on the interfaces between the first conductivity type column region and the second conductivity type column region as well as the first conductivity type column region and the second conductivity type layer and the depletion layer formed between the first conductivity type region and the interface of the region provided with the first conductivity type region connect to each other.

3. The semiconductor device according to claim 1, wherein
a charge amount per unit area of the first conductivity type region is 2.0×10⁻⁸ C/cm² or higher.

4. The semiconductor device according to claim 1, wherein
a charge amount per unit area of the first conductivity type region is 3.0×10⁻⁷ C/cm² or lower.

5. The semiconductor device according to claim 1, wherein
the first conductivity type region is provided on an entire surface of the second conductivity type column region in a planar direction of the semiconductor substrate.

6. The semiconductor device according to claim 1, wherein
the first conductivity type region is provided in a part of the second conductivity type column region in a planar direction of the semiconductor substrate, and
the second conductivity type column region connects to the second conductivity type layer.

7. The semiconductor device according to claim 6, wherein
the first conductivity type column region and the second conductivity type column region are provided to extend in one direction parallel to the planar direction of the semiconductor layer and aligned repetitively in a direction orthogonal to the one direction, and
a length of the first conductivity type region in an alignment direction of the first conductivity type column region and the second conductivity type column region is shorter than a length of the second conductivity type column region in the alignment direction.

8. The semiconductor device according to claim 7, wherein
a ratio of a length of the first conductivity type column region in the alignment direction with respect to the length of the second conductivity type column region in the alignment direction is 3 or less, and the length of the first conductivity type region in the alignment direction is 33% or more of the length of the second conductivity type column region in the alignment direction.

9. The semiconductor device according to claim 6, wherein
the first conductivity type column region and the second conductivity type column region are provided to extend in one direction parallel to the planar direction of the semiconductor layer and aligned repetitively in a direction orthogonal to the one direction, and
a length of the first conductivity type region in the one direction is shorter than a length of the second conductivity type column region in the one direction.

10. The semiconductor device according to claim 9, wherein
a ratio of a length of the first conductivity type column region in an alignment direction of the first conductivity type column region and the second conductivity type column region with respect to a length of the second conductivity type column region in the alignment direction is 3 or less, and a length of the first conductivity type region in the one direction is 33% or more of a length of the second conductivity type column region in the one direction.

11. The semiconductor device according to claim 1, wherein
the first conductivity type region is provided to a surface-layer portion of the second conductivity type column region.

12. The semiconductor device according to claim 1, wherein
the first conductivity type region is provided between a surface-layer portion of the second conductivity type column region and a bottom portion of the second conductivity type column region opposite to the surface-layer portion.

13. The semiconductor device according to claim 1, wherein
the first conductivity type region includes a plurality of first conductivity type regions provided to the second conductivity type column region in a thickness direction of the semiconductor substrate.
